(19) United States
(12) Patent Application Publication
(10) Pub. No.: US 2006/0134903 A1
(43) Pub. Date: Jun. 22, 2006

(54) Connection ball positioning method and device for integrated circuits

(75) Inventors: Mohamed Boufnichel, Tours (FR); Patrick Hougron, Parcay Meslay (FR); Vincent Jarry, La Membrolle Sur Choisille (FR)

Correspondence Address: Bryan A. Santarelli;GRAYBEAL JACKSON HALEY LLP, 155 - 108th Avenue NE. , Suite 350, Bellevue, WA, 98004-5973, US

(73) Assignee: STMicroelectronics SA

(21) Appl. No.: 11/315,447

(22) Filed: Dec. 21, 2005

(30) Foreign Application Priority Data
Dec. 21, 2004 (FR) 04/53119

(51) Int. Cl. H01L 21/44; B23K 31/02

(52) U.S. Cl. 438/614; 438/613; 228/180.22

(57) ABSTRACT

Forming conductive bumps on an integrated circuit wafer by sucking in conductive balls into cavities of a mask, placing the mask supporting the balls on the integrated circuit wafer, temporarily attaching the mask and the wafer together, cutting the suction, and submitting the mask and wafer assembly to a thermal ball melting processing.

### PRIORITY CLAIM

This application claims priority from French patent application No. 04/53119, filed Dec. 21, 2004, which is incorporated herein by reference.

### BACKGROUND

1. Field of the Invention

An embodiment of the present invention generally relates to the manufacturing of integrated circuits and, more specifically, to the placing of conductive balls on an integrated circuit wafer to form electric connection conductive bumps.

2. Discussion of the Related Art

Increasingly, the assembly of an integrated circuit on a support with contact transfer, be it on a printed circuit or on another integrated circuit, is performed by conductive bumps ensuring the contacts between the integrated circuit and its support. Such bumps are generally supported by the integrated circuit to be assembled on its support and are formed by melting conductive balls (generally made of a tin and lead alloy) arranged on reception areas formed in a dedicated metallization (UBM or Under Bump Metallization) on a surface of the integrated circuit.

An embodiment of the present invention more specifically relates to the forming of conductive bumps and especially to the placing of conductive balls to form such bumps.

A first known so-called flow technique consists of depositing by means of a mask prints of an adhesive material on conductive ball receive areas. Then, the balls are positioned on these prints by means of a second mask and are temporarily maintained by the adhesive, thus enabling removing the second mask for the heating. A disadvantage of this technique is the presence of the temporary adhesion layer which is likely to form air micro-bubbles between the balls and the wafer, subsequently generating degassings, i.e., breaking of the micro-bubbles.

A second so-called no-flow technique to which an embodiment of the present invention more specifically applies consists of carrying out the conductive ball melting step while the mask for positioning these balls still is present on the wafer, thus avoiding the temporary holding glue.

FIGS. 1 and 2 show, respectively in exploded perspective view and in cross-section view, a conventional example of a tool for placing conductive balls in a no-flow conductive bump forming method.

A wafer 1 (for example, made of silicon) supporting active and/or passive integrated circuits (not shown), and intended to receive on a surface 11 conductive balls for forming conductive bumps, is placed on a stainless steel bearing 2. Bearing 2 is formed of an internal collar 21 on which rests the surface 12 of wafer 1 opposite to that intended to receive the balls, and of an external collar 22 of diameter greater than the diameter of wafer 1 to be processed. Collars 21 and 22 are interconnected by radial tabs 23, regularly distributed between the two collars.

A molybdenum mask 3 is placed on surface 11 of wafer 1 and comprises hoes 31 above the ball reception areas provided on wafer 1. For clarity, the dimensions have been exaggerated in the drawings and only a few holes 31 have been shown. In practice, the number of conductive balls (and thus of holes 31 in mask 3) is of several tens of thousands per wafer (on the order of 50,000 balls with a diameter of approximately 300 μm for a wafer with a diameter of some fifteen centimeters—6 inches).

A stainless steel ring 4 is placed on mask 3 and comprises feet 41 which cross peripheral orifices 32 of mask 3 and orifices 24 of tabs 23 of support 2. Finally, stainless steel clips 5 are arranged at the periphery to maintain the different elements together.

Orifices 32 (and possibly 24) have a diameter such as to enable a clearance of feet 41 at least with respect to mask 3. This clearance is used for the accurate positioning of mask 3 with respect to wafer 1, which is performed by centering crosses, respectively 33 and 13, formed in mask 3 and in wafer 1. The need for a physical contact between mask 3 and wafer 1 to prevent the balls from passing between these two elements imposes a deformation of wafer 1 and of the mask, which are bulged (FIG. 2) under the effect of the peripheral pinch and of internal collar 21.

Once the tool has been assembled with a wafer 1 and a mask 3 such as illustrated in FIG. 2, it is used until the end of the forming of the conductive bumps.

FIGS. 3A, 3B, and 3C illustrate, in very simplified cross-section views of the ball positioning tool, a conventional example of a method for forming conductive bumps by positioning of conductive balls through a molybdenum mask 3 in a no-flow technique.

In a first step, balls 6 of a conductive material are poured in bulk on mask 3 supported by the previously-described tool.

Then, horizontal vibrations or motions are imposed to the tool so that balls 6 come into holes 31 of mask 3 on the basis of one ball to a hole, the hole diameter and the mask thickness being selected according to the diameter of balls 6. The additional balls are eliminated from the surface of mask 3, for example, by shaking the assembly. An assembly such as illustrated in FIG. 3B is then obtained.

This assembly is then submitted to a thermal processing (symbolized by a radiating element 7, FIG. 3C) to melt balls 6 and obtain the conductive bumps. After cooling, the tool is disassembled and a wafer (not shown) provided with conductive bumps at contact areas is obtained. This wafer is then cut to individualize the integrated circuit chips.

The technique of no-flow conductive bump forming by means of a tool such as described hereabove has several disadvantages.

A first disadvantage is the obligation to impose a curvature to wafer 1 to ensure a contact between its upper surface (11, FIG. 1) and the lower surface of mask 3, which generates mechanical stress likely to damage the wafer.

Another disadvantage is the thermal mass of the tool which generates significant thermal processing times to reach the ball melting temperature.

Another disadvantage is the deformation of the molybdenum mask in the thermal processing which, since it exhibits an expansion coefficient different from that of the silicon wafer, is likely to generate ball alignment defects with respect to their respective reception areas. This disadvantage limits the diameters of the wafers likely to be processed by such a method.

Another disadvantage of this technique is that it is in practice limited to balls of a diameter of several hundreds of micrometers (typically, 300 μm and more). Indeed, to guarantee the presence of a single-ball per hole, the mask thickness approximately corresponds to the ball diameter. Now, it cannot be envisaged to further decrease the mask thickness for mechanical hold reasons.

### SUMMARY

An embodiment of the present invention aims at overcoming all or some of the disadvantages of known methods and tools of conductive bump forming by a no-flow technique.

An embodiment of the present invention more specifically aims at providing a solution enabling forming bumps from conductive balls of a diameter smaller than 300 μm, preferably, smaller than or equal to 100 μm.

An embodiment of the present invention also aims at providing a solution compatible with the deposition of conductive balls whatever the wafer diameter.

An embodiment of the present invention also aims at providing a solution which improves the thermal efficiency.

To achieve all or some of these features, as well as others, an embodiment of the present invention provides a mask for positioning conductive balls on an integrated circuit wafer, comprising, in a first surface, cavities for individually receiving the balls, each cavity communicating with a second surface of the mask by a channel with a cross-section smaller than the cavity cross-section.

According to an embodiment of the present invention, the opening of each cavity in the first surface has a shape such that a single ball can engage with a clearance into this cavity.

According to an embodiment of the present invention, the depth of each cavity is greater than the diameter of the balls for which the mask is intended.

According to an embodiment of the present invention, the cross-section and the depth of the cavities are identical and enable engagement with clearance of a single ball.

According to an embodiment of the present invention, the cross-section of the cavities is smaller than 100 μm.

According to an embodiment of the present invention, the mask further comprises through openings of constant cross-section.

According to an embodiment of the present invention, the mask is made of silicon.

An embodiment of the present invention also provides a method for depositing and positioning conductive balls on an integrated circuit wafer, comprising:
sucking in conductive balls into cavities of a mask;
placing the mask supporting the balls on the integrated circuit wafer; and
temporarily attaching the mask and the wafer together.

According to an embodiment of the present invention, the suction is performed by placing the second surface of the mask against a suction plate connected, preferably, to a vacuum pump.

An embodiment of the present invention also provides a method for forming conductive bumps on an integrated circuit wafer, comprising:
sucking in conductive balls into cavities of a mask;
placing the mask supporting the balls on the integrated circuit wafer;
temporarily attaching the mask and the wafer together;
cutting the suction; and
submitting the mask and wafer assembly to a thermal ball melting processing.

### BRIEF DESCRIPTION OF THE DRAWINGS

The foregoing and other features and advantages of the present invention will be discussed in detail in the following non-limiting description of specific embodiments in connection with the accompanying drawings.

FIG. 1, previously described, is a simplified exploded perspective view of a conventional tool for positioning conductive balls.

FIG. 2, previously described, is a simplified cross-section view of the tool of FIG. 1 once assembled.

FIGS. 3A, 3B, and 3C, previously described, illustrate a conventional example of the method for forming conductive bumps by means of the tool of FIGS. 1 and 2.

FIG. 4 shows a mask for depositing conductive balls on an integrated circuit wafer according to an embodiment of the present invention.

FIGS. 5A, 5B, and 5C illustrate, in simplified cross-section views, an embodiment of the method according to the present invention for forming conductive bumps on a wafer from conductive balls.

FIG. 6 is a partial cross-section view illustrating another embodiment of the present invention.

### DETAILED DESCRIPTION

For clarity, same elements have been designated with same reference numerals in the different drawings and, further, as usual in the representation of integrated circuits, the various drawings are not drawn to scale. For clarity still, only those elements and steps which are necessary to the understanding of the described embodiments of the present invention have been shown in the drawings and will be described hereafter. In particular, the forming of the conductive areas for receiving the conductive bumps on the integrated circuit wafer has not been detailed, embodiments of the present invention being compatible with any conventional forming.

According to an embodiment of the present invention, a mask for depositing conductive bumps on a wafer supporting active and/or passive integrated circuits comprises individual housings open on a first surface of the mask and communicating with suction channels of smaller cross-section emerging on the other mask surface. Each housing being sized to be able to contain with clearance a whole ball.

FIG. 4 partially shows in cross-section a mask 8 for depositing and positioning semiconductor balls according to an embodiment of the present invention.

This embodiment of the present invention will be described hereafter in relation with a preferred embodiment of a silicon mask 8. It, however, more generally applies to any material likely to be machined according to different diameters across its thickness and which does not wet the materials constitutive of the balls to be deposited (generally, of a tin and lead or tin and silver alloy). Preferably, this material is selected to have an expansion coefficient close to that of the wafers to be processed, although this is not required.

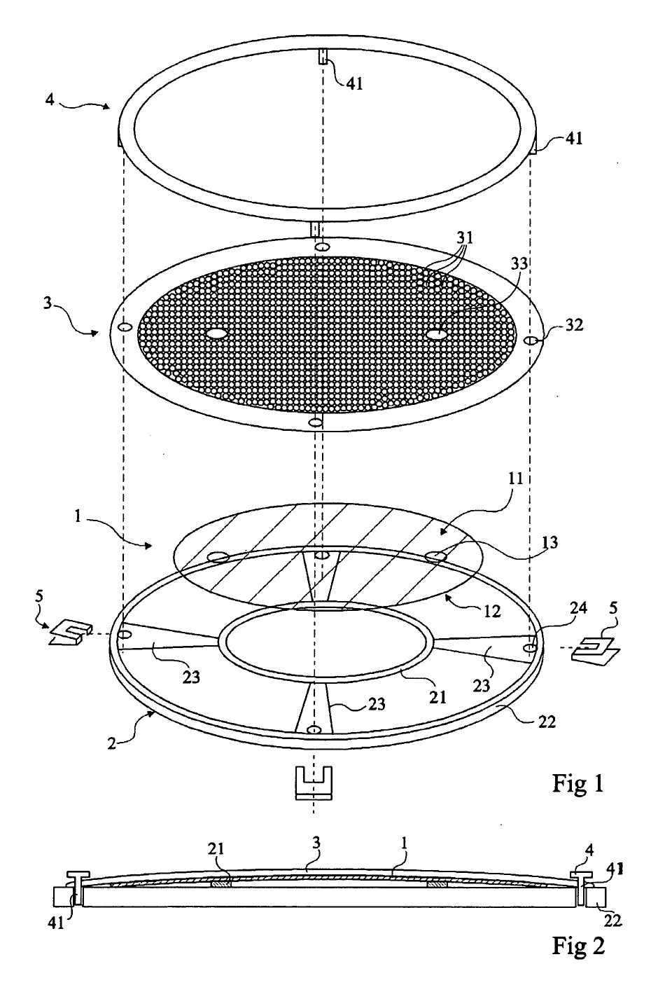

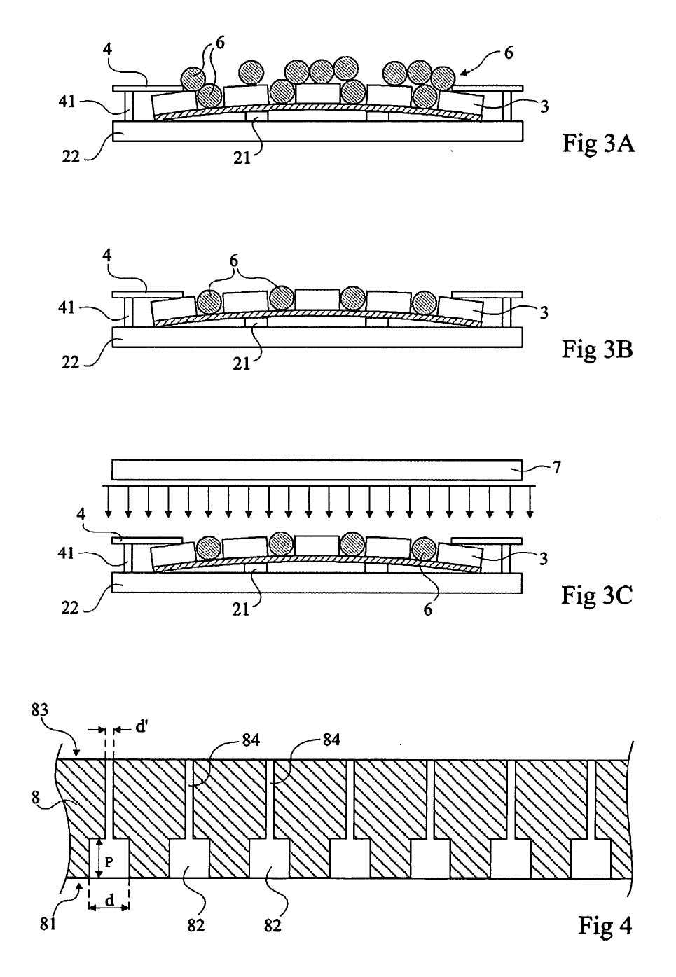

As illustrated in FIG. 4, cavities 82, each for receiving a ball, are formed from a first surface 81 of mask 8 intended to rest against the integrated circuit wafer surface (11, FIG. 1). Preferably, cavities 82 are circular and have a depth p, which may be identical to or greater than their diameter d. Each cavity 82 communicates with the other surface 83 of mask 8 by a suction channel 84. Each channel 84 is, for example, a circular hole bored in mask 8 and exhibits a diameter d′ smaller than the diameter of the balls to be deposited, and thus smaller than diameter d.

The forming of such a structure in masks formed of a silicon wafer is particularly easy. For example, through holes of diameter d′ may be bored in the silicon wafer by means of a laser. Then, cavities 82 may be etched by plasma.

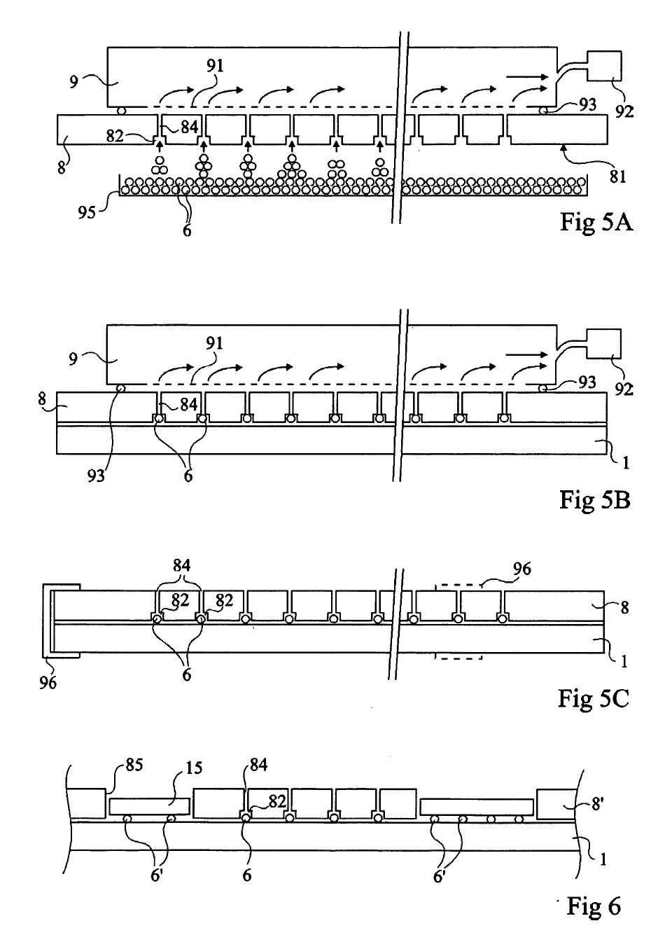

FIGS. 5A, 5B, and 5C illustrate, in cross-section views, an embodiment of the method of conductive ball deposition on a wafer 1.

As illustrated in FIG. 5A, a mask 8 comprising cavities 82 and suction channels 84 distributed according to the pattern of the conductive balls to be positioned is associated with an suction plate 9. This plate comprises a surface 91 provided with suction orifices communicating with a pump, for example, a vacuum pump 92. A peripheral seal 93 is provided between mask 8 and wafer 9 which are maintained together, for example, by clips not shown. The assembly is then brought above a container 95 containing conductive balls 6 in bulk.

As illustrated in the left-hand portion of FIG. 5A, the balls are sucked in towards cavities 82 until a ball is housed in each available cavity. Once a ball is housed at the bottom of its cavity 82 by suction, it closes the corresponding channel 84, which automatically causes the fall of the other balls which had been attracted by mask 8. This effect is improved in case of an electrostatic coating of surface 81 of mask 8.

As illustrated in FIG. 5B, the assembly of mask 8 and wafer 9 is placed on a silicon wafer 1 intended to receive the balls. As an alternative, wafer 1 is placed on mask 8. The centering of mask 8 with respect to wafer 1 is performed, for example, conventionally (crosses 33 and 13, FIG. 1).

As illustrated in FIG. 5C, wafer 1 is, once properly positioned, temporarily attached to mask 8 by means of clips 96, preferably regularly distributed around the wafer. The suction can then be stopped and suction plate 9 may be separated from mask 8. Balls 6 are then released and rest on wafer 1, properly positioned above the provided receive areas.

The structure thus formed can then be introduced into a furnace to melt balls 6 and obtain the conductive bumps.

After cooling, clips 96 are removed to release mask 8 from wafer 1.

An advantage of this embodiment of the present invention is that it is no longer necessary for the mask to have the same thickness as the diameter of the balls to be deposited. Accordingly, it is possible to deposit balls of small diameters (80 μm or even less) with a mask of a thickness of several hundreds of μm, and thus of a sufficient rigidity.

Another advantage of this embodiment of the present invention is that with materials having similar or identical expansion coefficients, risks of ball mispositioning are avoided. This embodiment of the present invention thus becomes compatible with the deposition and the positioning of conductive balls on wafers on the order of some thirty centimeters (12 inches), or even more.

Another advantage of this embodiment of the present invention is that it avoids use of a stainless steel tool to maintain the mask on the wafer, which reduces the thermal mass of the assembly and improves the furnace cycle efficiency.

Another advantage of this embodiment of the present invention is that the deposition method remains with no flow.

FIG. 6 illustrates, in a partial cross-section view, another embodiment of the present invention.

According to this embodiment, mask 8′, in which cavities 82 and suction channels 84 have been formed, comprises through openings 85 in areas intended for the placing of integrated circuit chips 15 on wafer 1. It may be, for example, the placing of integrated circuits on other circuits (not shown) formed in wafer 1. Each circuit 15 supports, on its surface intended to rest on wafer 1, conductive bumps 6′ formed conventionally or by implementation of an embodiment of the present invention on wafers having supported circuits 15.

Such a variation enables positioning at the same time the balls for forming conductive bumps and the integrated circuits to be placed on wafer 1, which are then assembled thereto at the same time as the bumps are formed. After, and conventionally, the integrated circuits chips are individualized from wafer 1 by cutting.

Openings 85 in mask 8′ may, for example, be formed by means of a laser while channels 84 will be formed by laser or by plasma etch and cavities 82 are formed by plasma etch.

According to another simplified embodiment of the present invention, more specifically intended for applications on wafers of relatively small diameter (on the order of some twenty centimeters), and to balls with a relatively large diameter (for example, on the order of 300 μm), mask 8 is made of molybdenum. In this case, channels 84 are formed by laser while the cavities are formed, for example, by electrochemical etch. Such an embodiment already has the advantage of avoiding, due to the use of a system of ball deposition by suction, use of a stainless steel tool, and of thus improving the thermal efficiency. Further, this avoids many handlings of the tool for the assembly of a wafer and the ball deposition.

Of course, the present invention is likely to have various alterations, improvements, and modifications which will readily occur to those skilled in the art. In particular, other methods for forming cavities and suction channels than those indicated as an example may be envisaged, such methods compatible with the material used for the mask and with the machining of a structure of at least two different cross-sections across the mask thickness. Further, although the forming of channels of a single diameter is a described embodiment, it can be envisaged to form channels having stepped diameters between cavities 82 and rear surface 83 of the mask, especially if this is required by the selected machining techniques. Moreover, some or all of the channels 84 may open along a side surface of the mask 8 instead of along the rear surface 83.

A wafer processing system may include the mask 8 for use as described above.

Such alterations, modifications, and improvements are intended to be part of this disclosure, and are intended to be within the spirit and the scope of the present invention. Accordingly, the foregoing description is by way of example only and is not intended to be limiting.

What is claimed is:

1. A mask for positioning conductive balls on an integrated circuit wafer, comprising, in a first surface, cavities for individually receiving the balls, each cavity communicating with a second surface of the mask by a channel with a cross-section smaller than the cavity cross-section and being able to contain with clearance a whole ball.

2. The mask of claim 1, wherein the opening of each cavity in the first surface has a shape such that a single ball can engage with a clearance into this cavity.

3. The mask of claim 1, wherein the depth of each cavity is greater than the diameter of the balls for which the mask is intended.

4. The mask of claim 1, wherein the cross-section and the depth of the cavities are identical and enable engagement with clearance of a single ball.

5. The mask of claim 1, wherein the cross-section of the cavities is smaller than 100 μm.

6. The mask of claim 1, wherein the mask further comprises through openings of constant cross-section.

7. The mask of claim 1, made of silicon.

8. A method for depositing and positioning conductive balls on an integrated circuit wafer, comprising:
sucking in conductive balls into cavities of the mask of claim 1;
placing the mask supporting the balls on the integrated circuit wafer; and
temporarily attaching the mask and the wafer together.

9. The method of claim 8, wherein the suction is performed by placing the second surface of the mask against a suction plate connected to a vacuum pump.

10. A method for forming conductive bumps on an integrated circuit wafer, comprising:
sucking in conductive balls into cavities of the mask of claim 1;
placing the mask supporting the balls on the integrated circuit wafer;
temporarily attaching the mask and the wafer together;
cutting the suction; and
submitting the mask and wafer assembly to a thermal ball melting processing.

11. An element-placing member, comprising:
first and second surfaces;
cavities formed in the first surface and each operable to receive a respective element to be placed, the element having a width; and
channels formed in the second surface and each operable to couple a suction to a respective one of the cavities and having a respective width that is smaller than the width of the element.

12. The element-placing member of claim 11 wherein the first surface is opposite to the second surface.

13. The element-placing member of claim 11 wherein the first surface is contiguous with the second surface.

14. The element-placing member of claim 11 wherein the cavities, elements, and channels each have respective substantially circular cross sections.

15. The element-placing member of claim 11 wherein each of the cavities is operable to receive only a single one of the elements.

16. The element-placing member of claim 11 wherein the elements comprise respective electrical-connection balls.

17. A wafer-processing system, comprising:
a member having first and second surfaces,
cavities formed in the first surface of the member and each operable to receive a respective element to be placed, the element having a width, and
channels formed in the second surface of the member and each operable to couple a suction to a respective one of the cavities and having a respective width that is smaller than the width of the element.

18. The wafer-processing system of claim 17, further comprising a vacuum plate operable to engage the second surface of the member and to generate suction in the cavities via the channels.

19. A method, comprising:
sucking elements into respective cavities of a placement member;
positioning the member over a predetermined portion of a receiving member; and
releasing the elements onto the receiving member.

20. The method of claim 19 wherein sucking the elements comprises:
coupling a suction plate to the placement member; and
generating a suction in the cavities using the suction plate.

21. The method of claim 19 wherein sucking the elements comprises:
locating a first surface of the placement member over a number of elements that is greater than a number of the cavities; and
generating a suction in the cavities to pull a respective one of the elements into each of the cavities.

22. The method of claim 19, further comprising:
wherein positioning the placement member comprises aligning the placement member with the predetermined portion of the receiving member; and
securing the aligned placement member to the receiving member.

23. The method of claim 19 wherein positioning the placement member comprises positioning the placement member over the entire receiving member.

24. The method of claim 19 wherein:
sucking the elements into the cavities comprises generating suction in the cavities; and
releasing the elements comprise halting the generating of the suction.

25. The method of claim 19, further comprising:
wherein sucking the elements comprises sucking connection elements into the respective cavities of the placement member;
wherein releasing the elements comprises releasing the connection elements onto a wafer; and
after releasing the connection elements onto the wafer, heating the connection elements to form connection bumps on the wafer.

26. The method of claim 19, further comprising:
wherein sucking the elements comprises sucking a respective connection element into each of the cavities of the placement member;
wherein releasing the elements comprises releasing the connection elements onto a wafer;
after releasing the connection elements onto the wafer, moving the placement member away from the wafer; and
after moving the placement member away from the wafer, heating the connection elements to form connection bumps on the wafer.
